(19) United States
(12) Patent Application Publication
(10) Pub. No.: US 2025/0364422 A1
(43) Pub. Date: Nov. 27, 2025

(54) ELECTRONIC MODULE AND ELECTRONIC APPARATUS

(71) Applicant: CANON KABUSHIKI KAISHA, Tokyo (JP)

(72) Inventors: TAKASHI NUMAGI, Tokyo (JP); HISAYUKI TAMURA, Kanagawa (JP)

(21) Appl. No.: 19/214,813

(22) Filed: May 21, 2025

(30) Foreign Application Priority Data
May 27, 2024 (JP) 2024-085774

(51) Int. Cl. H01L 23/538; H01L 23/00

(52) U.S. Cl. CPC H01L 23/5384; H01L 23/5383; H01L 24/06; H01L 2224/06131

(57) ABSTRACT

In an electronic module, a first via connected to a first terminal of a first terminal group of a first semiconductor element and a second via connected to a second terminal of the first terminal group are arranged in a first direction. A fourth via adjacent to a third via is arranged in a second direction intersecting the first direction. A virtual straight line connecting the first via and the second via passes between the third via and the fourth via. A first wiring connecting the first via and the fifth via connected to the fifth terminal of the third terminal group of the second semiconductor element and a second wiring connecting the second via and the sixth via connected to the sixth terminal of the third terminal group pass between the third via and the fourth via.

### BACKGROUND

### Field of the Technology

The present disclosure relates to an electronic module and an electronic apparatus.

### Description of the Related Art

Japanese Patent Laid-Open No. 2014-16867 discloses a memory system comprising a memory controller having a plurality of transmission terminals, a memory element having a plurality of terminals, and a printed wiring board on which the memory controller and the memory element are mounted. The transmission terminal of the memory controller and the reception terminal of the memory element are electrically connected by bus wiring provided on the printed wiring board. The memory controller controls the memory element by transmitting a control signal for a command signal and an address signal to the memory element through a bus line. Each of the memory controller and the memory element has a data terminal for transmitting and receiving a data signal. The data terminal of the memory controller is electrically connected to the data terminal of the memory element through a data signal line of the printed wiring board.

In order to process a large amount of data at high speed, increasing communication speed in an electronic module is required. For example, a memory interface, which is an example of an electronic module, operates in synchronization with a clock signal. When the frequency of the clock signal becomes higher due to the speedup, the cycle of the clock signal becomes shorter. The control signal operates in synchronization with the clock signal. Therefore, in order to increase the communication speed, it is required to reduce the variation in the time during which the control signal is received by the memory element.

Therefore, an object of the present disclosure is to provide an electronic module and an electronic apparatus capable of realizing high communication speed.

### SUMMARY

According to an aspect of the present disclosure, there is provided an electronic module comprising: a wiring board; and a first semiconductor element and a second semiconductor element that are mounted on one main surface of the wiring board, wherein the first semiconductor element includes a first terminal group and a second terminal group, wherein the second semiconductor element includes a third terminal group and a fourth terminal group, wherein the wiring board includes: a plurality of wiring layers; a first via group that has a plurality of through-vias respectively connected to a plurality of terminals of the first terminal group; a second via group that has a plurality of through-vias respectively connected to a plurality of terminals of the second terminal group; a third via group that has a plurality of through-vias respectively connected to a plurality of terminals of the third terminal group; and a fourth via group that has a plurality of through-vias respectively connected to a plurality of terminals of the fourth terminal group, wherein the first terminal group of the first semiconductor element is connected to the third terminal group of the second semiconductor element through the first via group and the third via group, and the second terminal group of the first semiconductor element is connected to the fourth terminal group of the second semiconductor element through the second via group and the fourth via group, wherein the first via group includes: a first via that is connected to a first terminal of the first terminal group; and a second via that is connected to a second terminal of the first terminal group, wherein the second via group includes: a third via that is connected to a third terminal of the second terminal group; and a fourth via that is connected to a fourth terminal of the second terminal group and is adjacent to the third via, wherein the third via group includes: a fifth via that is connected to a fifth terminal of the third terminal group; and a sixth via that is connected to a sixth terminal of the third terminal group, wherein the first via and the second via are arranged in a first direction, the first via and the second via overlap the first semiconductor element, the third via and the fourth via are arranged in a second direction intersecting the first direction, a virtual straight line that connects the first via and the second via passes between the third via and the fourth via, and a first wiring connecting the first via and the fifth via and a second wiring connecting the second via and the sixth via pass between the third via and the fourth via.

Features of the present disclosure will become apparent from the following description of embodiments with reference to the attached drawings. The following description of embodiments are described by way of example.

### BRIEF DESCRIPTION OF THE DRAWINGS

FIG. 1 is a perspective view illustrating an example of an electronic apparatus according to an embodiment.

FIG. 2 is an explanatory view schematically illustrating an example of the overall configuration of the electronic module according to the embodiment.

FIG. 3 is a cross-sectional view illustrating a structure of wiring layers and vias in the electronic module according to the embodiment.

FIG. 4 is a plan view illustrating the arrangement structure of terminals in a memory element according to the embodiment.

FIG. 5A is a wiring diagram schematically illustrating a positional relationship between control terminals and vias and a connection structure in a wiring layer of a printed wiring board according to the embodiment.

FIG. 5B is a wiring diagram schematically illustrating a connection structure between command/address signal lines and vias in a wiring layer of the printed wiring board according to the embodiment.

FIG. 5C is a wiring diagram schematically illustrating a connection structure between command/address signal lines and vias in a wiring layer of the printed wiring board according to the embodiment.

FIG. 6A is a wiring diagram schematically illustrating a positional relationship between control terminals and vias and a connection structure in the wiring layer of the printed wiring board according to the embodiment.

FIG. 6B is a wiring diagram schematically illustrating a connection structure between the command/address signal lines and vias in the wiring layer of the printed wiring board according to the embodiment.

FIG. 6C is a wiring diagram schematically illustrating a connection structure between the command/address signal lines and vias in the wiring layer of the printed wiring board according to the embodiment.

FIG. 7 is a plan view schematically illustrating a command/address signal line according to an Example 1.

FIG. 8A is a wiring diagram schematically illustrating a positional relationship between control terminals and vias and a connection structure in a wiring layer of a printed wiring board according to the Example 1.

FIG. 8B is a wiring diagram schematically illustrating a connection structure between command/address signal lines and vias in a wiring layer of the printed wiring board according to the Example 1.

FIG. 8C is a wiring diagram schematically illustrating a connection structure between command/address signal lines and vias in the wiring layer of the printed wiring board according to the Example 1.

FIG. 9A is a diagram illustrating a simulation waveform according to the Example 1.

FIG. 9B is a diagram illustrating a simulation waveform according to the Example 1.

FIG. 9C is a diagram illustrating a simulation waveform of the Example 1.

FIG. 10 is a plan view schematically illustrating command/address signal lines according to an Example 2.

FIG. 11A is a wiring diagram schematically illustrating a connection structure between the command/address signal lines and vias in a wiring layer of a printed wiring board according to the Example 2.

FIG. 11B is a wiring diagram schematically illustrating a connection structure between the command/address signal lines and vias in the wiring layer of the printed wiring board according to the Example 2.

FIG. 11C is a wiring diagram schematically illustrating a connection structure between the command/address signal lines and vias in the wiring layer of the printed wiring board according to the Example 2.

FIG. 12A is a wiring diagram schematically illustrating a connection structure between command/address signal lines and vias in a wiring layer of a printed wiring board according to a Reference Example.

FIG. 12B is a wiring diagram schematically illustrating a connection structure between command/address signal lines and vias in a wiring layer of the printed wiring board according to the Reference Example.

FIG. 12C is a wiring diagram schematically illustrating a connection structure between the command/address signal lines and vias in the wiring layer of the printed wiring board according to the Reference Example.

FIG. 13A is a diagram illustrating a simulation waveform of the Reference Example.

FIG. 13B is a diagram illustrating a simulation waveform of the Reference Example.

FIG. 13C is a diagram illustrating a simulation waveform of the Reference Example.

### DESCRIPTION OF THE EMBODIMENTS

Hereinafter, embodiments of the present disclosure will be described in detail with reference to the drawings. Note that the present disclosure is not limited to the following embodiments and can be appropriately changed without departing from the gist of the present disclosure. In the drawings described below, components having the same functions are denoted by the same reference numerals, and description thereof is omitted or simplified. Components having the same or similar functions but different configurations are denoted by the same names and different reference numerals, and the components can be distinguished from each other by appropriately adding ordinal numbers such as the first and second.

### Embodiment

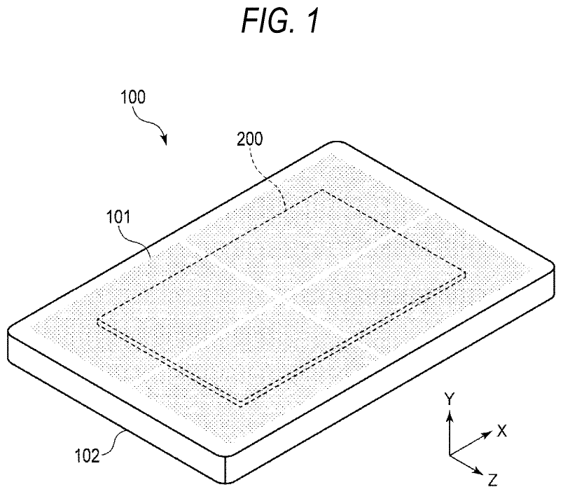

An electronic module and an electronic apparatus using the electronic module according to an embodiment of the present disclosure will be described concerning FIGS. 1 to 6C.

FIG. 1 is a perspective view illustrating an example of an electronic apparatus 100 according to the present embodiment. The electronic apparatus 100 is not particularly limited but is a digital device such as an imaging apparatus, a display device, an office device, a printing device, an industrial device, or a medical device. The electronic apparatus 100 may include an imaging apparatus 101 that manages information, such as images. The electronic apparatus 100 may include a circuit device that manages image data corresponding to an image. The imaging apparatus 101 is, for example, an image acquisition device or an image forming device. The image acquisition device is, for example, an imaging apparatus using a sensor, a drawing device using a user input, or an image generation device using artificial intelligence. The image forming apparatus is, for example, a display device or a printing device. The circuit device can be at least one of a storage device, a communication device, a control device, an input/output device, and an arithmetic device (processing device). For example, the circuit device may output image data based on an image signal obtained by the image acquisition device. The image forming apparatus forms an image based on the image data output from the circuit device. In a camera, a circuit device outputs image data based on an image signal obtained by an imaging apparatus such as a CMOS image sensor, and a display device such as a liquid crystal display or an organic EL display displays (forms) an image based on the image data output by the circuit device. In a copier, a circuit device outputs image data based on an image signal obtained by an imaging apparatus such as a scanner, and an electrophotographic or inkjet printing device prints (forms) an image based on the image data output by the circuit device. Not only a copier but also a single-function scanner and a single-function printer may include a circuit device and an imaging apparatus.

In the example illustrated in FIG. 1, the electronic apparatus 100 is an X-ray flat panel detector that can be used as a medical device. As illustrated in FIG. 1, the electronic apparatus 100 includes an imaging apparatus 101, an electronic module 200, and a housing 102. The circuit device included in the electronic apparatus 100 includes the electronic module 200. The electronic module 200 is provided on the back surface of the imaging apparatus 101 and is disposed inside the housing 102 together with the imaging apparatus 101. The imaging apparatus 101 in the X-ray flat panel detector is an imaging apparatus that outputs image data corresponding to electromagnetic waves such as X-rays incident on the imaging apparatus 101. The imaging apparatus 101 includes a scintillator, a photodiode, a thin film transistor array, an analog-to-digital converter, a low noise amplifier, and the like, which are not illustrated.

The electronic module 200 is a printed circuit board. The electronic module 200 is connected to the imaging apparatus 101 so as to control the imaging apparatus 101. The imaging apparatus 101 is an electronic module separate from the electronic module 200. In addition, image data output from the imaging apparatus 101 is input to the electronic module 200. The electronic module 200 stores the input image data. The electronic module 200 performs image processing on the input image data. Further, the electronic module 200 transmits the image data to another electronic module through an interface such as a LAN (Local Area Network) or a USB (Universal Serial Bus). Thus, the electronic module 200 is a circuit device that can function as a control device, a storage device, a processing device, an input/output device, and a communication device. The electronic module 200, as the first electronic module, is connected to the second electronic module.

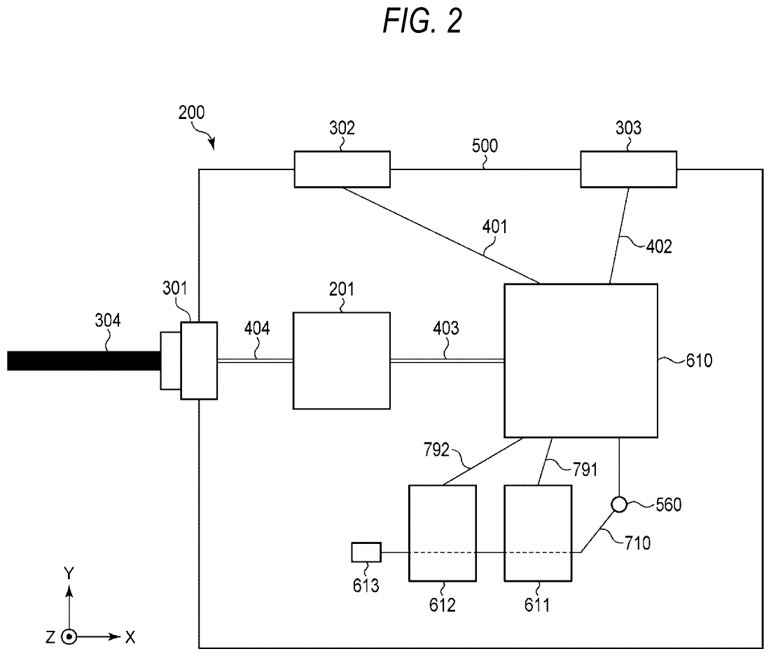

FIG. 2 is an explanatory diagram schematically illustrating an overall configuration example of the electronic module 200 according to the present embodiment. As illustrated in FIG. 2, the electronic module 200 includes a memory element 611, which is an example of a first semiconductor element, a memory element 612, which is an example of a second semiconductor element, and a memory controller 610, which is an example of a third semiconductor element. The memory controller 610 inputs and outputs data to and from the memory elements 611 and 612. The electronic module 200 includes a connector 301, a connector 302, a connector 303, a conversion chip 201, a resistor 613, and a printed wiring board 500. The memory element 611, the memory element 612, the memory controller 610, the connector 301, the connector 302, the connector 303, the conversion chip 201, and the resistor 613 are mounted on one main surface of the printed wiring board 500. The printed wiring board 500 is, for example, a rigid board. The printed wiring board 500 includes a wiring 401, a wiring 402, a wiring 403, a wiring 404, a command/address signal line 710, a data signal line 791, and a data signal line 792.

The memory elements 611 and 612 are the same type of memory element. The memory elements 611 and 612 are, for example, double data rate (DDR) 4 memories. The memory elements 611 and 612 are not limited to DDR4 memories and may be memories of other standards or other types.

The connectors 302 and 303 are each connected to the imaging apparatus 101 through a wiring member (not illustrated) such as a cable or a flexible substrate. Image data is input to the connector 302 and the connector 303 from the imaging apparatus 101 through the respective cables. The connectors 302 and 303 are electrically connected to the memory controller 610 through the wirings 401 and 402 of the printed wiring board 500. The image data input to the connector 302 and the image data input to the connector 303 are output to the memory controller 610 through the wirings 401 and 402, respectively.

The memory controller 610 stores image data in the memory elements 611 and 612. The memory controller 610 reads image data stored in the memory elements 611 and 612. The memory controller 610 is electrically connected to the conversion chip 201 through the wiring 403 of the printed wiring board 500. The memory controller 610 outputs the processed image data to the conversion chip 201 through the wiring 403.

The conversion chip 201 is electrically connected to the connector 301 through the wiring 404 of the printed wiring board 500. A cable 304 (wiring member) is connected to the connector 301. The conversion chip 201 converts the image data transmitted from the memory controller 610 into image data in a format defined by a communication standard. Further, the conversion chip 201 outputs the converted image data to the cable 304 through the wiring 404 and the connector 301. The cable 304 is a wiring member that mutually connects the electronic modules and is connected to, for example, a computer for image display. The computer for image display is also an electronic module. The image data is input to the computer through the cable 304 and is subjected to processing such as display processing on a display and storage processing on a storage device in the computer.

Each of the memory controller 610, the memory elements 611 and 612 is configured as one semiconductor package. Each of the memory elements 611 and 612 is electrically connected to the memory controller 610 through data signal lines 791 and 792 of the printed wiring board 500. Each of the data signal line 791 and the data signal line 792 is a bus wiring including a plurality of wirings. Thus, a transmission path of image data (data signal) is formed between the memory element 611 and the memory controller 610 and between the memory element 612 and the memory controller 610.

Further, the memory controller 610 and the memory elements 611 and 612 are electrically connected to each other by the command/address signal line 710 of the printed wiring board 500. The command/address signal line 710 is a bus wiring including a plurality of signal lines. Thus, a transmission path of the command signal and the address signal is configured between the memory controller 610 and each memory element 611 and 612.

The memory controller 610 transmits a command signal and an address signal to the memory elements 611 and 612 by a parallel transmission method through the command/address signal line 710. The command signal and the address signal, which are parallel signals transmitted from the memory controller 610, are received by the two memory elements 611 and 612 through the command/address signal line 710. The memory controller 610 controls the memory elements 611 and 612 by transmitting a control signal, the command signal, and the address signal to the memory elements 611 and 612 through the command/address signal line 710. Each memory elements 611 and 612 stores and erases image data in accordance with the command signal and the address signal from the memory controller 610.

As described above, the memory system is configured by the memory controller 610, the memory element 611 and 612, and the printed wiring board 500. The memory system is configured as a printed circuit board.

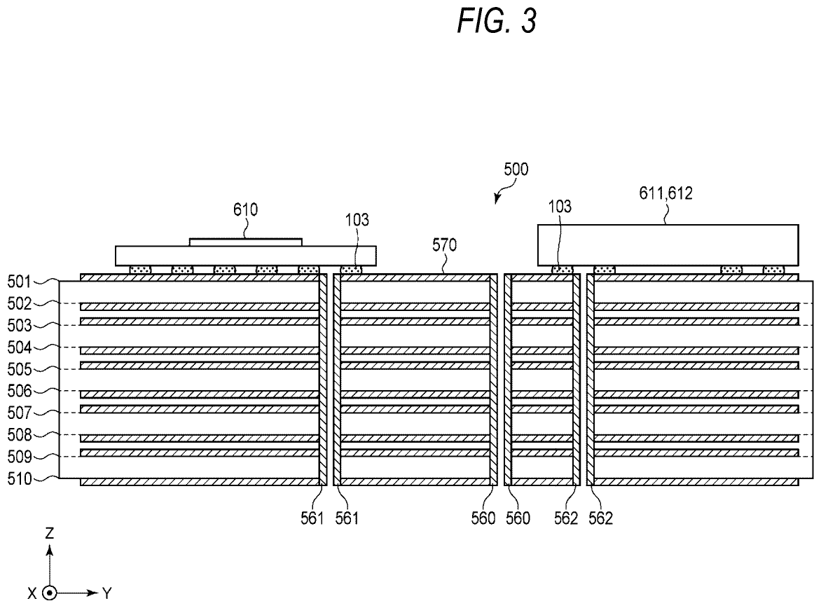

FIG. 3 is a cross-sectional view illustrating the electronic module 200 according to the present embodiment. The printed wiring board 500 includes a base material having an insulating property and a conductive conductor constituting wiring. The base material is, for example, a glass epoxy resin. The material of the conductor is, for example, copper. The memory controller 610 and the memory elements 611 and 612 are mounted on the printed wiring board 500. Components other than the memory controller 610, the memory elements 611 and 612 may be mounted on the printed wiring board 500.

The printed wiring board 500 is a laminated substrate having a plurality of wiring layers. The printed wiring board 500 illustrated in FIG. 3 has, for example, wiring layers for 10 layers 501 to 510. The wiring layers 501 to 510 are stacked in a direction (Z direction in the drawing) perpendicular to the main surface of the printed wiring board 500. The base material (that is, an insulating layer) (not illustrated) is provided between the wiring layers 501 to 510. The wiring layers 501 to 510 are arranged in the order of a wiring layer 501, a wiring layer 502, a wiring layer 503 (first wiring layer), a wiring layer 504, a wiring layer 505, a wiring layer 506, a wiring layer 507, a wiring layer 508, a wiring layer 509 (second wiring layer), and a wiring layer 510 in the Z direction. The wiring layers 501 and 510 have main surfaces of the printed wiring board 500. That is, the wiring layers 501 and 510 are surface layers that are mounting surfaces on which the memory controller 610, the memory element 611, the memory element 612, and the like can be mounted. The wiring layers 502 to 509 between the wiring layer 501 and the wiring layer 510 are inner layers. A protective film such as a solder resist (not illustrated) may be disposed on the surfaces of the wiring layer 501 and the wiring layer 510.

In each of the wiring layers 501 to 510, a conductor pattern 570, which is a conductor film constituting wirings, is formed. Further, a through-via (hereinafter, referred to as a “via”) 560, a via 561, and a via 562 constituting the wiring are disposed so as to straddle the wiring layers 501 to 510. The via 560, the via 561, and the via 562 are conductors formed in the through holes of the wiring layer.

FIG. 3 does not accurately illustrate a data signal line 711, a data signal line 712, and the command/address signal line 710 illustrated in FIG. 2, but schematically illustrates a cross section of the printed wiring board 500 in order to explain the wiring layers 501 to 510.

The memory controller 610 and the memory elements 611 and 612 are mounted on the wiring layer 501, which is one main surface. Components such as a capacitor and a resistor (not illustrated) are mounted on the wiring layers 501 and 510. A conductor pattern mainly serving as a ground is formed in the wiring layer 502 that is adjacent to the wiring layer 501 through an insulating layer. The same applies to the wiring layer 505 that is adjacent to the wiring layer 506 through an insulating layer. In the wiring layers 503 and 504, the conductor patterns serving as parts of wiring, such as the data signal line 711, the data signal line 712, and the command/address signal line 710, are mainly formed.

The memory controller 610 and the memory elements 611 and 612 are connected to the printed wiring board 500 by a solder 103. Each of the memory controller 610 and the memory elements 611 and 612 includes a plurality of signal terminals, a plurality of power supply terminals, and a plurality of ground terminals. Among the plurality of signal terminals, some (for example, 16) signal terminals are data terminals. Each terminal of the memory controller 610, the memory element 611, and the memory element 612 have a ball grid array structure in which the terminals are arranged in a matrix.

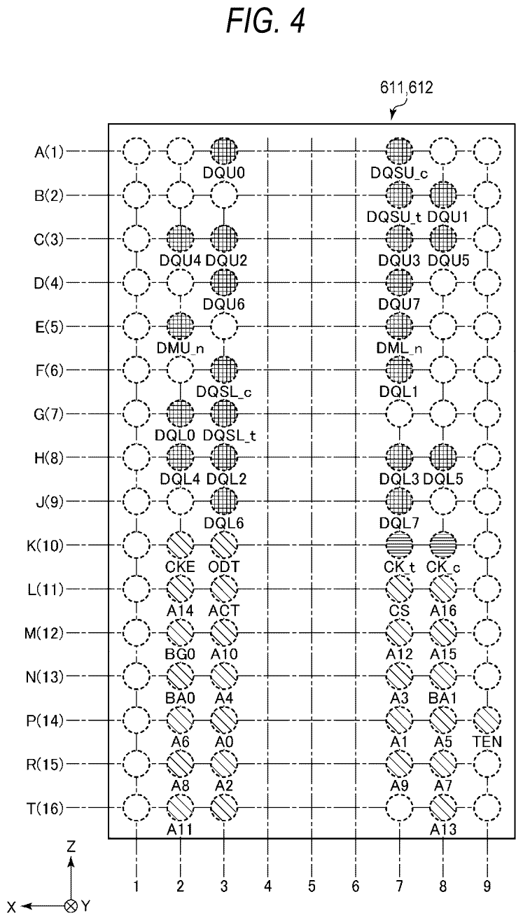

FIG. 4 is a plan view illustrating an arrangement structure of terminals in the memory elements 611 and 612. FIG. 4 illustrates a case where the memory elements 611 and 612 are viewed from a surface opposite to a surface on which terminals are arranged. In FIG. 4, each terminal is indicated by a dashed line.

The memory elements 611 and 612 are DDR4-SDRAMs. As illustrated in FIG. 4, in each of the memory elements 611 and 612, terminals are provided in the first column to the third column and the seventh column to the ninth column in a region divided into sixteen rows and nine columns. No terminals are provided in the fourth to sixth columns. The total number of terminals is 96.

In FIG. 4, among the plurality of terminals, the terminals indicated by diagonal lines are the command/address terminals CKE, CS, ODT, A0 to A16, BA0, BA1, BG0, ACT, PAR, and TEN. The command/address terminals are control terminals of the memory element and are arranged in the tenth to sixteenth rows and the second to the ninth column. The terminals indicated by a mesh are the data terminals DQU0 to DQU7, the data mask terminal DMU_n, the data strobe terminals DQSU_c and DQSU_t, the data terminals DQL0 to DQL7, the data mask terminal DML_n, and the data strobe terminals DQSL_c and DQSL_t. The data terminal, the data mask terminal, and the data strobe terminal are arranged in the first to ninth rows and the second to eighth columns. The clock terminal CK_t and the clock terminal CK_c are arranged in the seventh column and the eighth column of the tenth row. As for other terminals, an ALERT terminal, a RESET terminal, a power supply terminal, and a ground terminal (not illustrated) are included.

In general, the memory elements 611 and 612 are arranged so that their respective data terminals are directed toward the memory controller 610. The data terminal of each memory element 611 and 612 and the data terminal of the memory controller 610 are electrically connected to each other through the data signal line 711 and the data signal line 712.

In each of the memory elements 611 and 612, the command/address terminals are located on a side away from the memory controller 610. The command/address signal line 710 has a fly-by wiring structure including a plurality of wirings functioning as a plurality of signal lines. The command/address terminals of the memory elements 611 and 612 are electrically connected to the command/address terminals of the memory controller 610 through the command/address signal line 710. One end of the command/address signal line 710 is connected to the resistor 613. The resistor 613 is a termination element and is a chip resistor that is pull-up connected to a termination voltage. As illustrated in FIG. 2, the command/address signal line 710 can be connected to the memory elements 611 and 612 by wiring bent in a substantially L-shape.

Hereinafter, with reference to FIG. 4, a configuration of a memory interface in a case where wiring is connected to the command/address terminals of the memory elements 611 and 612 will be described. In the eight Gb addressing of the DDR4 memory, when a memory element having a data width of 16 bits is used, one clock enable signal (CKE) line, one chip select signal (CS) line, and one on-die termination signal (ODT) line are used. One bank group signal (BG) line, two bank address signal (BA) lines, and 17 address signal (A) lines are used. Further, one active command signal (ACT) line, one parity signal (PAR) line, and one test enable signal (TEN) line are used. Thus, a total of 26 signal lines are used.

The memory interface operates in synchronization with a clock signal. As the frequency of the clock signal becomes higher, the period of the clock signal becomes shorter. In order to increase the communication speed in the memory interface, it is effective to reduce the variation in the time at which the command/address signal output from the memory controller 610 reaches the memory elements 611 and 612. For example, the period of the command/address signal of the DDR3-800 memory interface is 2500 picoseconds. Assuming that the allowable value of the variation of the arrival time is 10% of the cycle, the allowable value is 250 picoseconds in terms of time. Assuming that the wiring delay time in the wiring of one mm is seven picoseconds, a variation in arrival time between command/address signal lines of about 35.7 mm is allowed. On the other hand, in the case of using the DDR4-2400 memory interface in which speeding up has been developed, the period of the address signal is 375 picoseconds. Assuming that the allowable value of the flickering of the arrival time is 10% of the cycle, the allowable value is 37.5 picoseconds in terms of time. In this case, the allowable variation in the length between the command/address signal lines is about 5.4 mm. As the speed-up progresses, it is required to further suppress the variation in the length of the wiring among the plurality of wirings constituting the command/address signal line.

As an example of a method of equalizing the lengths of the command/address signal lines, there is meander wiring. The meander wiring is a wiring structure in which the wiring length is adjusted by lengthening the wiring by a structure in which the wiring meanders. When the length of the wiring is to be made uniform by using the meander wiring, it is necessary to adjust the length of the bus wiring of the command/address signal so as to match the longest signal line. The wiring becomes longer as a whole. Therefore, when the communication speed in the memory interface is increased, the influence of the frequency loss of the electric signal due to the wiring cannot be ignored. Due to the frequency loss, the amplitude voltage drops, the rise time and the fall time of the signal waveform become long. Thereby, the voltage noise margin and the timing margin decrease. Therefore, the lengthening of the wiring becomes a cause of hindering the speeding up of the memory interface. In order to increase the communication speed in the memory interface, it is required to reduce the frequency loss of the electric signal due to the wiring, in other words, to shorten the wiring.

As described above, in order to increase the communication speed in the memory interface, it is required that, in the twenty-six wires connecting the control terminal of the memory element 611 and the control terminal of the memory element 612, the variation in the length of the wires is suppressed and the wire adjustment by the meander wire or the like is reduced.

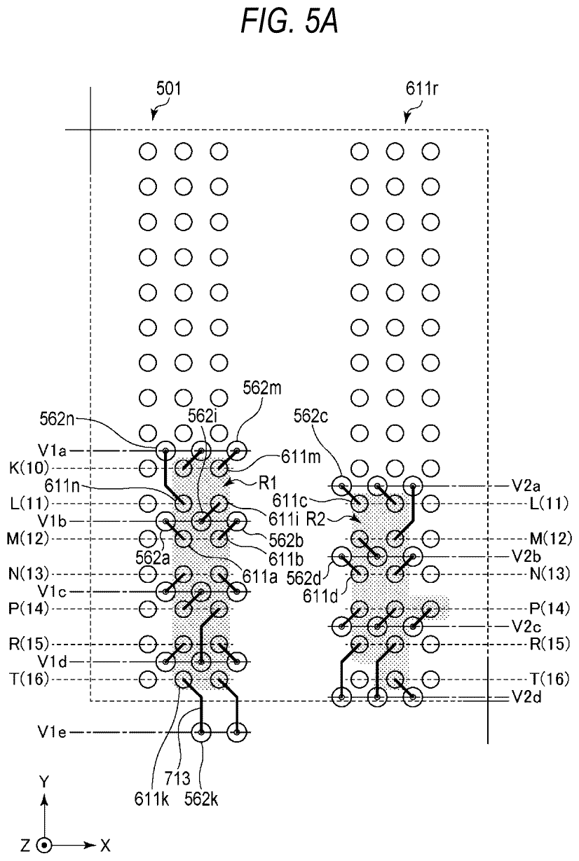

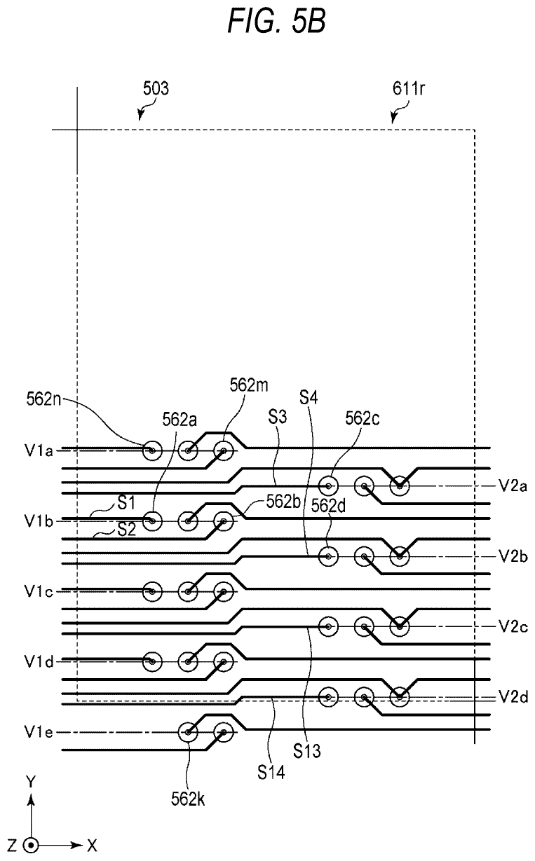

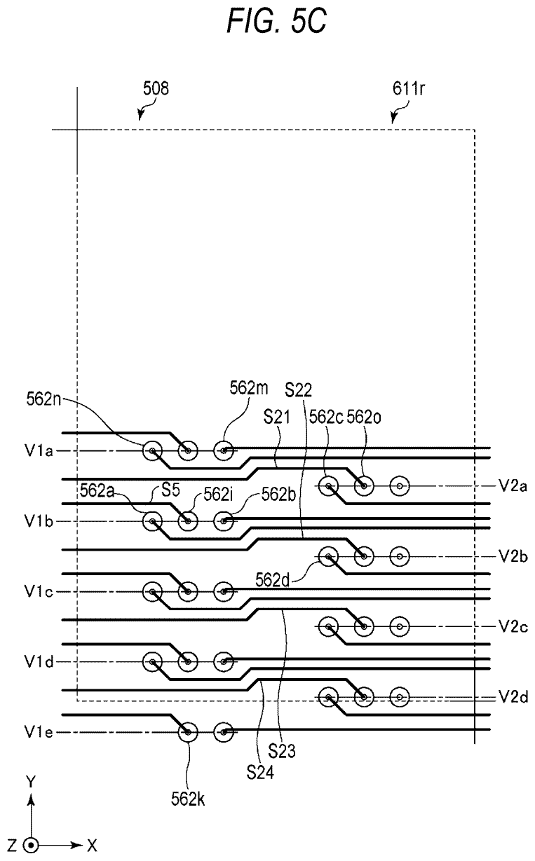

Hereinafter, a wiring structure of the command/address signal line 710 in the electronic module according to the present embodiment will be specifically described. FIG. 5A is a wiring diagram schematically illustrating a positional relationship between the control terminals and the vias in the wiring layer 501 of the printed wiring board 500 and the connection structure. A region 611r surrounded by a broken line indicates a region where the memory element 611 is mounted in the wiring layer 501. Among the region 611r, a region RI and a region R2 are regions in which control terminals of commands/addresses are arranged. The memory element 611 includes two terminal groups.

The first terminal group of the region R1 includes a plurality of terminals arranged in the second column and the third column from the tenth row to the sixteenth row. The second terminal group of the region R2 includes a plurality of terminals arranged in the seventh column and the eighth column from the eleventh row to the sixteenth row and the eighth column of the fourteenth column. In an electronic module in which a plurality of memory elements are mounted, control terminals having the same function are connected to each other by wiring. Therefore, the command/address wiring is wired in the left-right direction (X direction in the drawing) of the region 611r in which the memory element is arranged in FIG. 5A. Fourteen command/address wirings connected to the first terminal group cross, through the vias, the region R2 where the second terminal group is disposed, at an inner layer than the wiring layer 501. Similarly, twelve command/address wirings connected to the second terminal group cross the region R1 where the first terminal group is disposed, at the inner layer.

In FIG. 5A, vias are connected to the terminals of the first terminal group and the second terminal group, respectively. The printed wiring board 500 includes a first via group having a plurality of vias respectively connected to a plurality of terminals of the first terminal group and a second via group having a plurality of vias respectively connected to a plurality of terminals of the second terminal group in a region 611r where the memory element 611 is mounted.

Specifically, the via 562a (first via) of the first via group is connected to the control terminal 611a (first terminal) of the first terminal group. The via 562b (second via) of the first via group is connected to the control terminal 611b (second terminal) of the first terminal group. The control terminals 611a and 611b are arranged in row M(12). The via 562c (third via) of the second via group is connected to the control terminal 611c (third terminal) of the second terminal group. The control terminal 611c is arranged in row L(11). The via 562d (fourth via) of the second via group is connected to the control terminal 611d (fourth terminal).

The control terminal 611d is arranged in row N(13). The via 562d is adjacent to the via 562c in the Y direction. The via 562a and the via 562b are arranged in the X direction (first direction). The via 562a and the via 562b overlap the memory element 611 (first semiconductor element). The via 562c and the via 562d are arranged in the Y direction (second direction) intersecting the X direction. A virtual straight line connecting the via 562a and the via 562b passes between the via 562c and the via 562d. The control terminal 611a (first terminal) and the control terminal 611b (second terminal) are arranged in the X direction (fourth direction). The control terminal 611i (ninth terminal) and the control terminal 611b (second terminal) are arranged in the Y direction (third direction).

In FIG. 5A, the control terminal (A14 signal terminal) 611n is arranged in row L(11) and is connected to the via 562n by wiring. The via 562n is disposed in a row V1a apart from the row L(11). Similar structures are provided at multiple locations, as illustrated in FIG. 5A. By arranging the vias in this manner, in the first terminal group, the vias are arranged for five rows from the row V1a to the row V1e with respect to the number of rows of the control terminals arranged for seven rows from the row K(10) to the row T(16). In the first terminal group, the number of rows of vias is smaller than the number of rows of control terminals. The control terminals arranged in seven rows and two columns are matrix-converted into via arrangements of five rows and three columns.

Similarly, in the second terminal group, the control terminals are disposed for six rows from the L(11) row to the T(16) row, whereas the vias are disposed for four rows from the V2a row to the V2d row. Also, in the third terminal group, the number of rows of vias is smaller than the number of rows of control terminals. The control terminals arranged in six rows and two columns are matrix-converted into via arrangements of four rows and three columns.

As illustrated in FIG. 5A, the rows V1a, V1b, V1c, V1d, and V1e in which the vias connected to the first terminal group are arranged alternate with the rows V2a, V2b, V2c, and V2d in which the vias connected to the second terminal group are arranged.

FIG. 5B is a wiring diagram schematically illustrating a positional relationship between vias and wirings in the wiring layer 503 of the printed wiring board 500. A wiring S1 (first wiring) extending from the via 562a is a command/address wiring connected to a via (fifth via) on the memory element 612 side described later. A wiring S2 (second wiring) extending from the via 562b is a command/address wiring connected to a via (second via) on the memory element 612 side described later. The first signal (control signal) from the memory controller 610 is supplied to the memory elements 611 and 612 through the wiring S1. Similarly, the second signal (control signal) from the memory controller 610 is supplied to the memory elements 611 and 612 through the wiring S2.

In FIG. 5B, four command/address wirings are disposed between the via 562m and the via 562b. The wiring S3 connected to the via 562c becomes a substantially linear wiring because the wiring path is not obstructed by the via 562m and the via 562b. The linear wiring can connect the memory elements by a short wiring path. The wiring S3 is provided between the row V1a and the row V1b in the X direction. The same applies to the wiring S4 extending from the via 562d.

Further, since the plurality of vias are regularly arranged, the wirings can also be regularly arranged. Thus, for example, wirings having similar shapes, such as the wirings S3, S4, S13, and S14, can be used. By using wiring having a similar shape, it is possible to reduce variation in the length of wirings between memory elements. The wiring S1 (first wiring) and the wiring S2 (second wiring) extending from the via 562b have partially different shapes in FIG. 5B. However, the difference between the length of the wiring S1 and the length of the wiring S2 is preferably within a range of 10% or less of the length of a reference wiring (for example, the wiring S1 or the wiring S2), and more preferably 5% or less. Within this range, variations in the lengths of the two wires can be considered to be small.

FIG. 5C is a wiring diagram schematically illustrating a positional relationship of a plurality of vias in the wiring layer 508 of the printed wiring board 500. In row V1b, a via 562i (ninth via) is disposed between the via 562a and the via 562b. The via 562i is connected to the control terminal 611b (second terminal) of the first terminal group illustrated in FIG. 5A. A wiring S5 (fifth wiring) extending from the via 562i is connected to a via (tenth via) on the memory element 612 side described later. The wiring S1 and the wiring S2 are formed in the wiring layer 503 of the plurality of wiring layers. In contrast, the wiring S5 is formed in a wiring layer different from the wiring S1 and the wiring S2.

As illustrated in FIG. 5C, a plurality of vias are disposed between row V1a and row V1b. Two command/address wirings are disposed between the via 562b and the via 562m. The wiring S21 connected to the via 562o is a substantially linear wiring because the wiring path is not obstructed by the via 562b and the via 562m. Therefore, the wiring S21 can connect the memory elements by a short wiring path.

Further, since the vias are regularly arranged, the wirings may also be regularly arranged. For example, wirings having similar shapes, such as the wirings S21, S22, S23, and S24, can be used. Variation in the length of the wirings can be reduced between a plurality of wirings connecting the memory element 611 and the memory element 612.

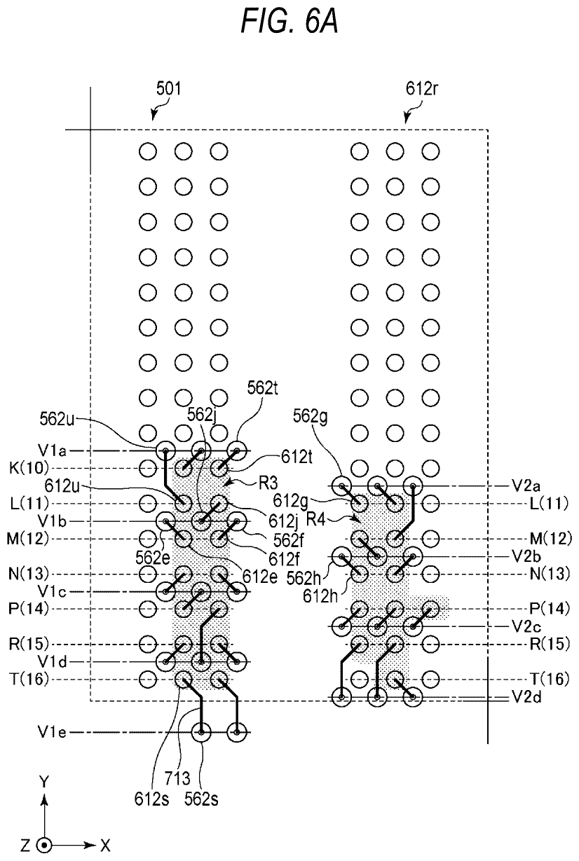

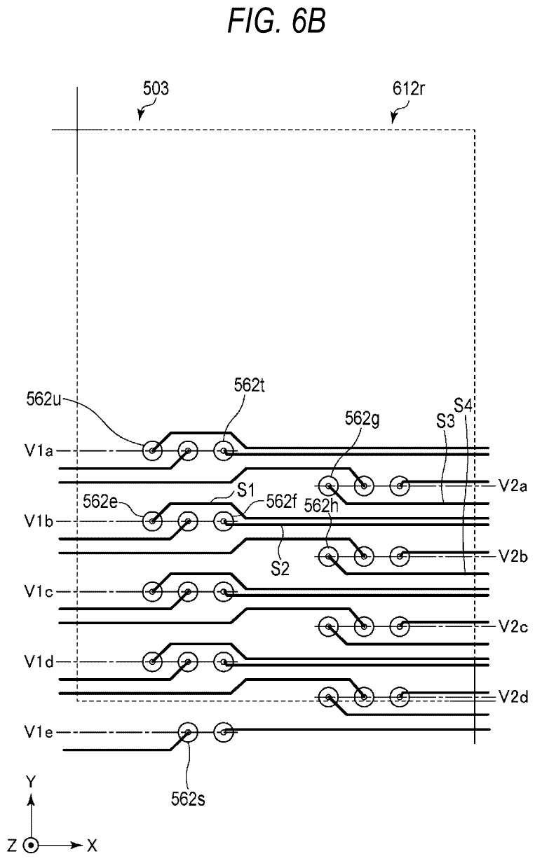

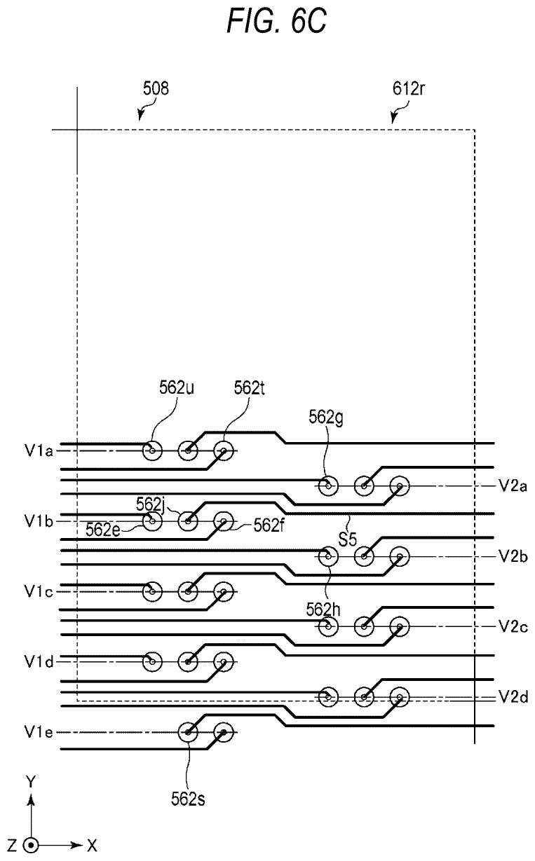

FIG. 6A is a wiring diagram schematically illustrating a positional relationship among control terminals, vias, and wirings in the wiring layer 501 of the printed wiring board 500. A region 612r surrounded by a broken line indicates a region where the memory element 612 is mounted in the wiring layer 501. Like the memory element 611, the memory element 612 includes two terminal groups. Among the region 612r, a region R3 and a region R4 are regions in which control terminals of commands/addresses are arranged.

The third terminal group of the region R3 includes a plurality of terminals arranged in the second column and the third column of the tenth row to the sixteenth row. The fourth terminal group of the region R4 includes a plurality of terminals arranged in seven columns, eight columns, and fourteen columns from the eleventh row to the sixteenth row. As in the case of FIG. 5A, the command/address wiring is wired in the left-right direction (X direction in the drawing) of the region 612r in which the memory element is arranged in FIG. 6A. Fourteen command/address wirings connected to the third terminal group cross the region R4 where the fourth terminal group is disposed in an inner layer than the wiring layer 501 through the vias. Similarly, twelve command/address wirings connected to the fourth terminal group cross, through the vias, the region R3 where the third terminal group is disposed, at an inner layer than the wiring layer 501.

In FIG. 6A, vias are connected to the control terminals of the third terminal group and the fourth terminal group, respectively. The printed wiring board 500 includes a third via group having a plurality of vias respectively connected to a plurality of terminals of the third terminal group and a fourth via group having a plurality of vias respectively connected to a plurality of terminals of the fourth terminal group in a region 612r where the memory element 612 is mounted. The first terminal group of the memory element 611 illustrated in FIG. 5A is connected to the third terminal group of the memory element 612 through the first via group and the third via group. Similarly, the second terminal group of the memory element 611 is connected to the fourth terminal group of the memory element 612 through the second via group and the fourth via group.

Specifically, a via 562e (fifth via) of the third via group is connected to a control terminal 612e (fifth terminal) of the third terminal group. A via 562f (sixth via) of the third via group is connected to the control terminal 612f (sixth terminal) of the third terminal group. A via 562g (seventh via) of the fourth via group is connected to a control terminal 612g (seventh terminal) of the fourth terminal group. A via 562h (eighth via) is connected to a control terminal 612h (eighth terminal). The via 562e and the via 562f are adjacent to each other in the Y direction. The via 562e and the via 562f are arranged in the X direction. The via 562g and the via 562h are arranged in the Y direction, intersecting the X direction. A virtual straight line connecting the via 562e and the via 562f passes between the via 562g and the via 562h. In the present embodiment, the memory element 611 and the memory element 612 are arranged on the main surface of the printed wiring board 500. Thereby, a virtual straight line connecting the via 562e and the via 562f and a virtual straight line connecting the via 562a and the via 562b are positioned on the same virtual straight line.

In FIG. 6A, the control terminal 612u is disposed in row L(11) and is connected to a via 562u by a wiring. The via 562u is disposed in row V1a apart from the row L(11) in the Y direction. Similar structures are provided at multiple locations. By arranging the vias in this manner, in the third terminal group, the vias are arranged for five rows from the row V1a to the row V1e with respect to the number of rows of the control terminals arranged for seven rows from the row K(10) to the row T(16). In the third terminal group, the number of rows of vias is smaller than the number of rows of control terminals.

Similarly, in the fourth terminal group, the control terminals are disposed for six rows from the row L(11) to the row T(16), whereas the vias are disposed for four rows from the row V2a to the row V2d. Also, in the fourth terminal group, the number of rows of vias is smaller than the number of rows of control terminals.

As illustrated in FIG. 6A, the rows V1a, V1b, V1c, V1d, and V1e, where the vias connected to the third terminal group are arranged alternately with the rows V2a, V2b, V2c, and V2d, where the vias connected to the fourth terminal group are arranged.

FIG. 6B is a wiring diagram schematically illustrating a positional relationship between vias and wirings in the wiring layer 503 of the printed wiring board 500. In FIG. 6B, a plurality of vias are disposed between row V2a and row V2b. Therefore, four command/address wirings can be arranged between the row V2a and the row V2b. The wiring S1 (first wiring) is a command/address wiring that connects the via 562e and the via 562a (first via) illustrated in FIG. 5A. The wiring S2 (second wiring) is a command/address wiring that connects the via 562f and the via 562b (second via) illustrated in FIG. 5A. The wiring S3 (third wiring) is a command/address wiring that connects the via 562g and the via 562c (third via) illustrated in FIG. 5A. The wiring S4 (fourth wiring) is a command/address wiring that connects the via 562h and the via 562d (fourth via) illustrated in FIG. 5A. The wiring S1 and the wiring S2 pass between the wiring S3 and the wiring S4. Since the wiring S1 is not obstructing the wiring path by the via 562g and the via 562h, the wiring SI becomes a substantially linear wiring. The same applies to the wiring S2 connected to the via 562f. The length of the wiring S1 corresponds to the length from the via 562a (first via) to the via 562e (fifth via), and the length of the wiring S2 corresponds to the length from the via 562b (second via) to the via 562f (sixth via). The length of the other wiring corresponds to the length between two vias to be connected, similar to the wiring S2.

Further, since the plurality of vias are regularly arranged, the wirings can also be regularly arranged. Thus, for example, wirings having similar shapes, such as the wirings S3 and S4, can be used. By using wiring having a similar shape, it is possible to reduce variation in length between wirings between memory elements.

FIG. 6C is a wiring diagram schematically illustrating a positional relationship between a plurality of vias in the wiring layer 508 of the printed wiring board 500. In row V1b, a via 562j (tenth via) is disposed between the via 562e and the via 562f. The via 562j is connected to the control terminal 611j (tenth terminal) of the third terminal group illustrated in FIG. 6A. The via 562j is connected to the via 562i (ninth via) illustrated in FIG. 5C by the wiring S5 (fifth wiring). The wiring S5 passes between the via 562g and the via 562h in the Y direction. The wiring S5 is not obstructing the wiring path by the via 562g and via 562h.

Further, since the vias are regularly arranged, the wirings may be regularly arranged. The wirings with a similar shape can also be used. When wiring having a similar shape is used, variation in length of the wiring between a plurality of wirings connecting the memory element 611 and the memory element 612 can be reduced.

As described above, according to the via arrangements of the present embodiment, it is possible to suppress the variation in the length of the wiring between the plurality of wirings and to reduce the wiring adjustment by the meander wiring or the like. Further, by suppressing the variation in the length of the wiring, it is possible to reduce the variation in the arrival time of the control signal received by the memory element. As a result, the communication speed in the memory interface can be increased.

Although the memory element (storage element) has been described as an example of the semiconductor element in the present embodiment, the semiconductor element in the electronic module 200 according to the present embodiment is not limited to the memory element. The semiconductor element in the electronic module 200 may be a sensor element, a display element, a control element, a power supply element, a communication element, an arithmetic element, a control element, or the like. The wiring board in the electronic module 200 may be a printed circuit board including a printed wiring board having a wiring structure similar to that of the printed wiring board 500.

### EXAMPLE

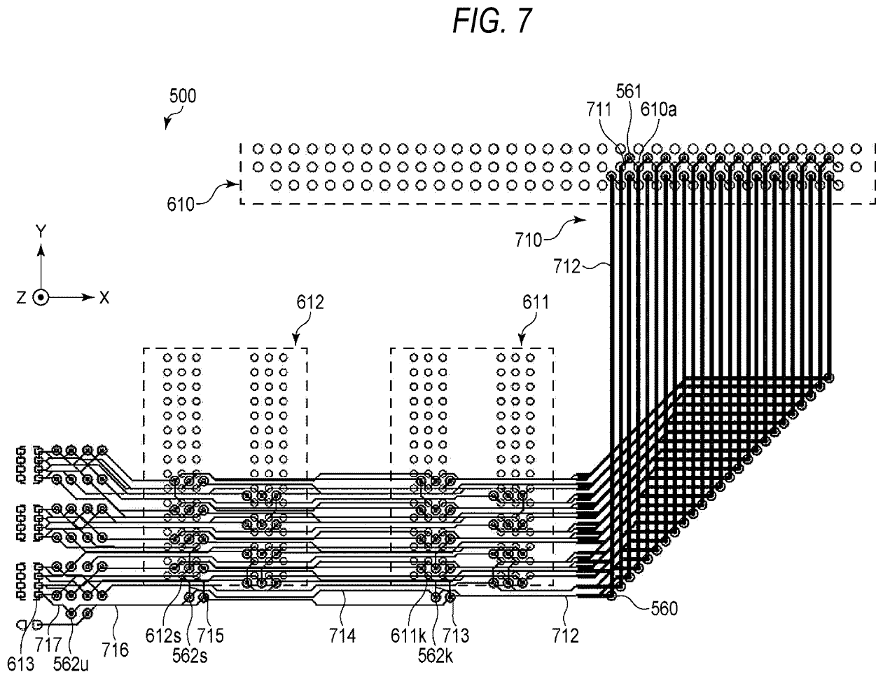

Next, with reference to FIGS. 7 to 13C, a more specific configuration of the printed wiring board 500 according to the present embodiment will be described using an Example 1, an Example 2, and a Reference Example.

### Example 1

FIG. 7 is a plan view schematically illustrating a command/address signal line according to the Example 1. As illustrated in FIG. 7, the memory controller 610 is disposed on the printed wiring board 500 so as to be apart from the memory elements 611 and 612 in the Y direction orthogonal to the X direction and the Z direction.

The command/address signal line 710 has a fly-by wiring structure. Hereinafter, a connection structure of one command/address wiring among command/address signal lines 710 for twenty-five will be described. The command/address terminal 610a of the memory controller 610 and the via 561 are connected by the data signal line 711 formed in a wiring layer 501, which is a surface layer of the printed wiring board 500. In the present description, the data signal line 711 is an inner layer wiring, but the data signal line 711 may be a surface layer wiring. The via 561 and the via 560 are connected to the data signal line 712 provided in the inner layer. The via 560 and the via 562a disposed close to the memory element 611 are connected by a data signal line 712 which is an inner layer wiring.

In the Example 1, the data signal line 712 is formed in the wiring layer 503. A via 562k and the control terminal 611k, which is a command/address terminal of the memory element 611, are connected by a surface layer wiring 713. The via 562k and a via 562s disposed close to the memory element 612 are connected by an inner layer wiring 714 formed in the wiring layer 508, which is an inner layer. The via 562s and the command/address terminal 612s of the memory element 612 are connected by a surface layer wiring 715 formed in the wiring layer 501, which is a surface layer. The via 562s and the via 562u are connected by a wiring 716 formed in the wiring layer 503, which is an inner layer. The via 562u and the resistor 613 are connected by a wiring 717 formed in the surface layer. As described above, the wiring connecting the first memory element and the second memory element has a structure in which the wiring layer is switched for each intervening via. Similarly, the wiring other than the command/address signal line 710 has a structure in which the wiring layer is switched for each via. The wiring layer connecting the memories is preferably an inner layer close to the surface layer. In the present embodiment, the wiring layer 502 and the wiring layer 509 of the inner layer are ground plane layers. The command/address wiring connecting the memories is disposed in the wiring layer 503 and the wiring layer 508 on the inner side of the ground plane layer.

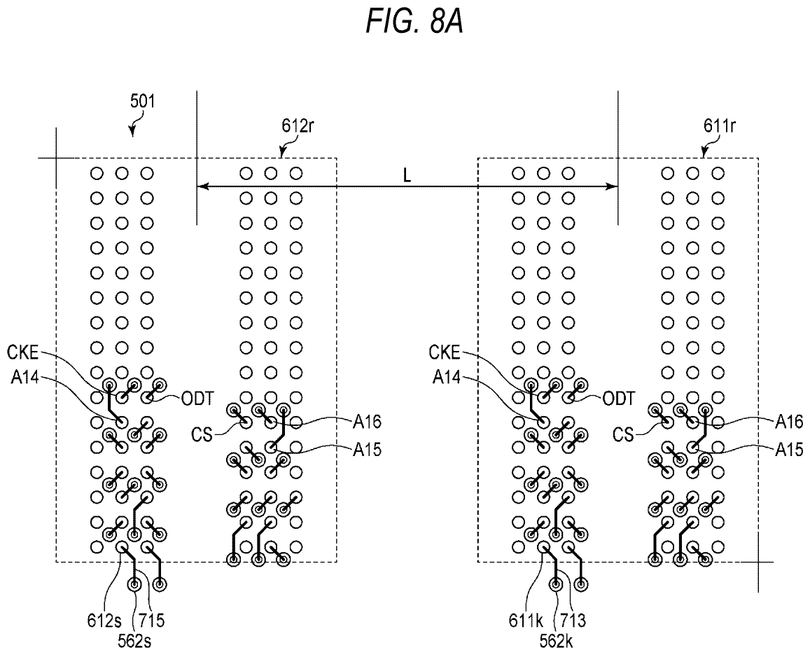

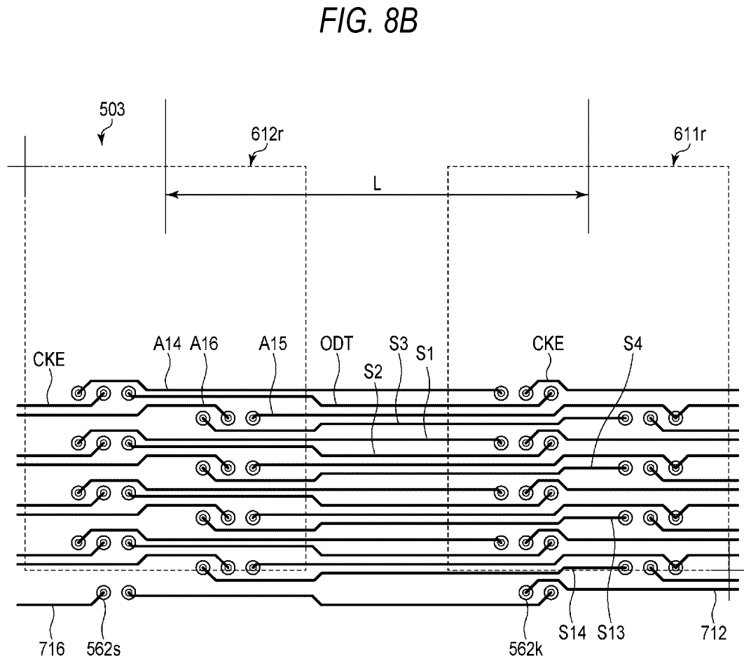

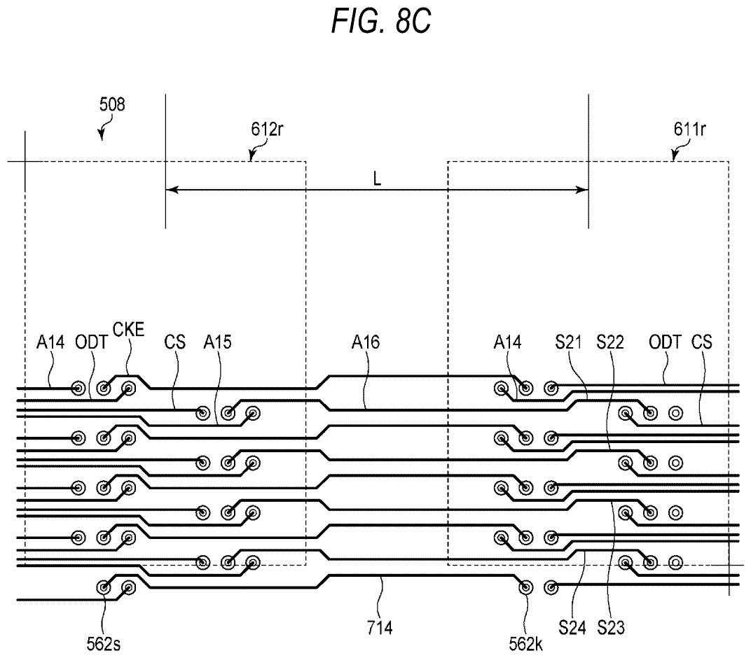

Subsequently, the structure of the command/address wiring connecting the memory element 611 and the memory element 612 will be described with reference to FIGS. 8A to 8C. FIG. 8A is a wiring structure diagram of the wiring layer 501 as viewed from the Z direction. FIG. 8B is a wiring structure diagram of the wiring layer 503. FIG. 8C is a wiring structure diagram of the wiring layer 508. The via arrangements in FIGS. 8A to 8C are similar to the via arrangements illustrated in FIGS. 5A to 6C. Command/address wiring connecting the memory elements 611 and 612 can be wired in a straight line. The linear wiring can connect the memory elements with a short wiring. Further, since the vias are regularly arranged, the wiring can also be regularly arranged. For example, the wirings S3, S4, S13, and S14 in FIG. 8B have similar shapes. Similarly, the wirings S21, S22, S23, and S24 in FIG. 8C have similar shapes. By using wiring having a similar shape, it is possible to reduce variation in length between wirings between memory elements.

In the Example 1, the center interval L between the memory elements 611 and 612 is 13.6 mm. Regarding the CKE signal wiring, the CS signal wiring, the ODT signal wiring, the A14 signal wiring, the A15 signal wiring, and the A16 signal wiring, the lengths of the inner layer wirings of the memory elements 611 and 612 are as illustrated in Table 1. The length, excluding the memory center interval of 13.6 mm, is 0.3 mm to 0.7 mm. It can be seen that the memories can be connected by a short wiring. The variation in length is 0.4 mm, and it can be seen that the variation in wiring length is suppressed. Since the length of the command/address wiring is short, the signal driving capability of the memory controller can be lowered. The variation in the length of the wiring between the plurality of wirings is preferably 10% or less, more preferably 5% or less of the length of the reference wiring.

TABLE 1

| Signal | |
|---|---|
| Name | Length (mm) |
| OKE | 14.3 |
| CS | 13.0 |
| ODT | 13.0 |
| A14 | 13.9 |
| A15 | 14.0 |
| A16 | 14.3 |

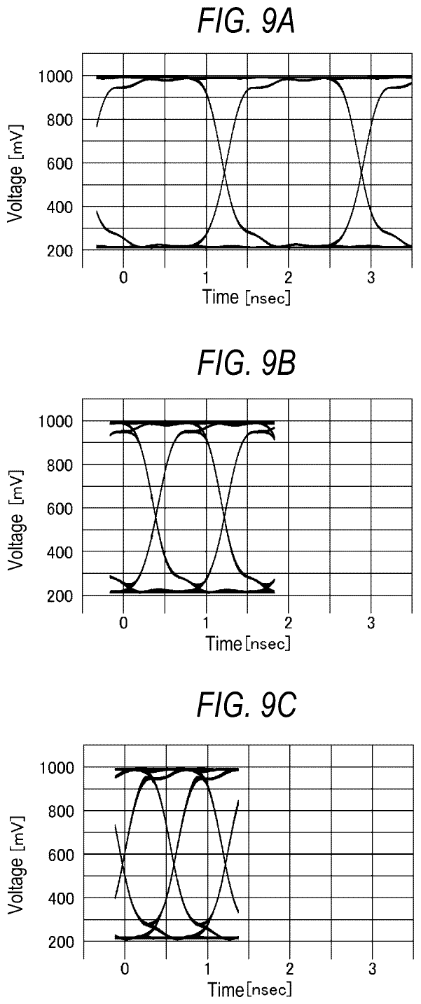

FIGS. 9A to 9C are waveform simulation results of the command/address signal according to the Example 1. In FIGS. 9A to 9C, the degradation of the waveform was compared when the data transfer rate was changed to 2400 Mbps, 4800 Mbps, and 6400 Mbps. Here, the amount of delay time variation (jitter) was observed under a voltage condition in which the rising edge and the falling edge of the waveform crossed each other. In FIGS. 9A to 9C, no significant increase in the delay time variation was observed. That is, it was confirmed that the command/address wiring of the Example 1 was suitable for increasing the communication speed in the memory interface.

As described above, according to the via arrangements illustrated in the Example 1, it is possible to suppress the variation in the length between the wirings and to reduce the wiring adjustment by the meander wiring or the like, so that it is possible to increase the communication speed in the memory interface.

### Example 2

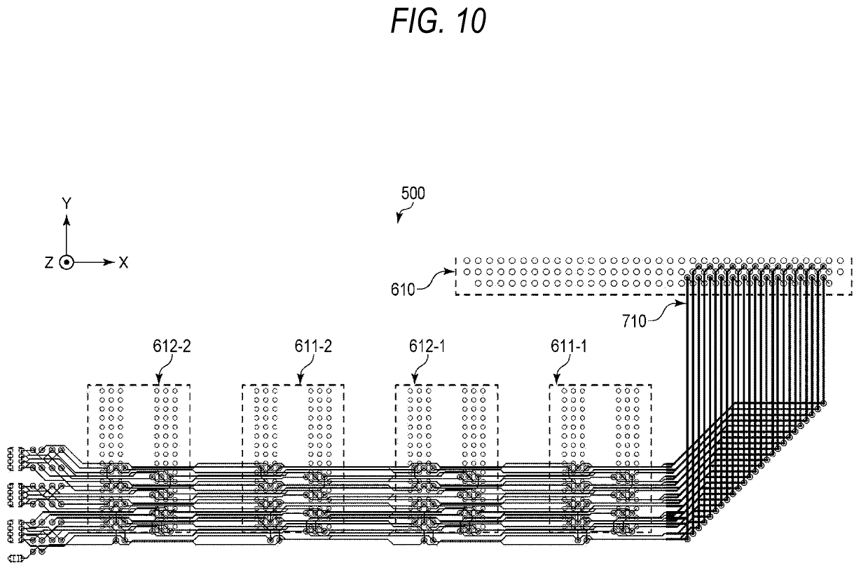

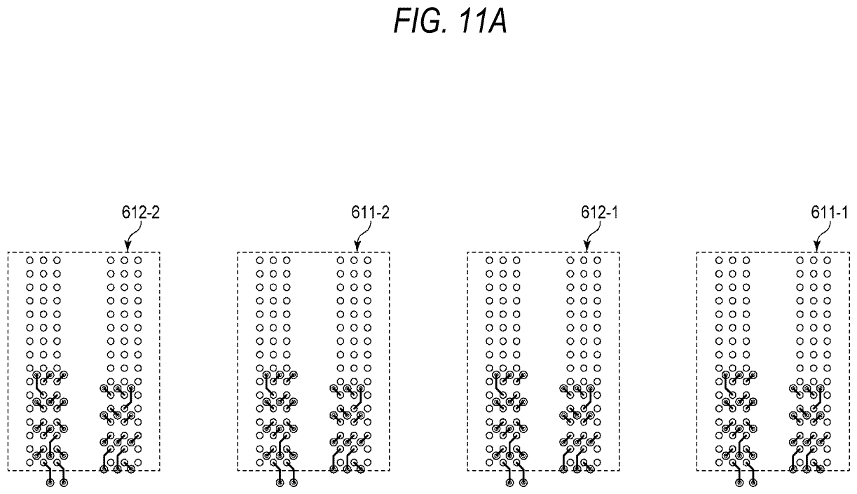

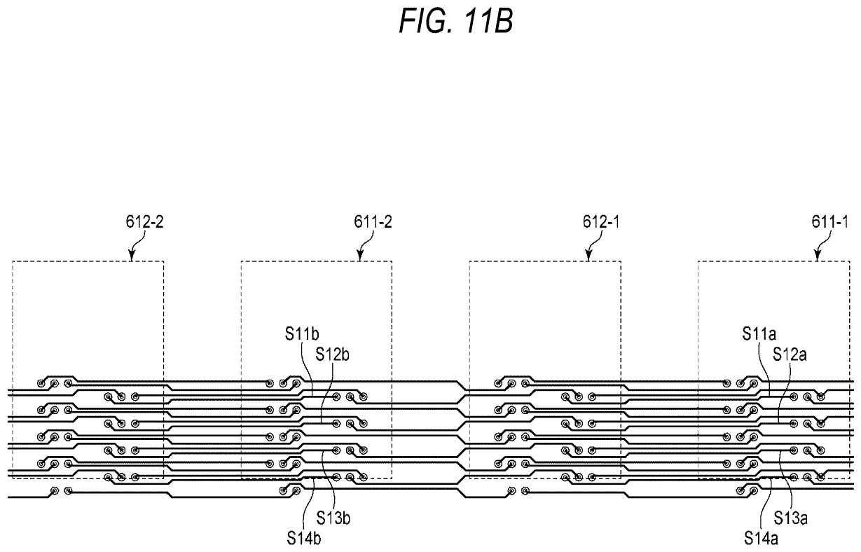

FIG. 10 is a plan view schematically illustrating a command/address signal line according to an Example 2. Here, a part of the memory controller 610 and a part of the memory elements 611 and 612 are illustrated when the electronic module 200 is viewed in a plan view, that is, when the electronic module 200 is viewed in the Z direction. FIGS. 11A to 11C are wiring diagrams schematically illustrating a connection structure between the command/address signal line and the via in the wiring layer of the printed wiring board according to the Example 2. As illustrated in FIG. 10, the memory controller 610 is disposed on the printed wiring board 500 at intervals in the Y direction with respect to the four memory elements (Memory element 611-1, memory element 612-1, memory element 611-2, and memory element 612-2).

Since the vias are regularly arranged, the wiring can also be regularly arranged. For example, wirings having similar shapes such as four wirings S11a, S12a, S13a, and S14a illustrated in FIG. 11B can be used. Like the wirings S11b, S12b, S13b, and S14b, wirings having similar shapes in the X direction can be used. Similarly, wirings having similar shapes in the Y direction can be used as the wirings S21a to S24a in FIG. 11C, and wirings having similar shapes in the X direction can be used as the wirings S21b to S24b.

As described above, according to the via arrangement illustrated in the Example 2, similar wirings can be used in the X direction and the Y direction. Even when the number of memory elements is increased, it is possible to suppress variations in length between wirings and to reduce wiring adjustment by meander wiring or the like. Thereby, it is possible to increase the communication speed in the memory interface.

### Reference Example

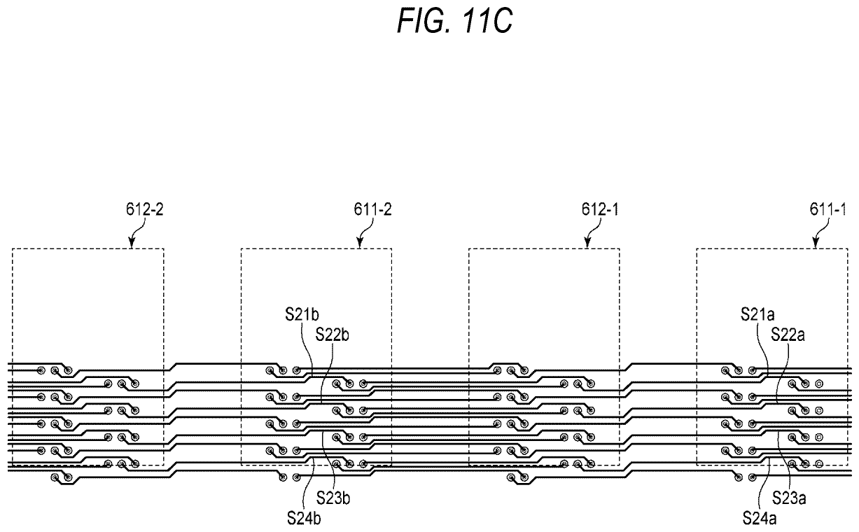

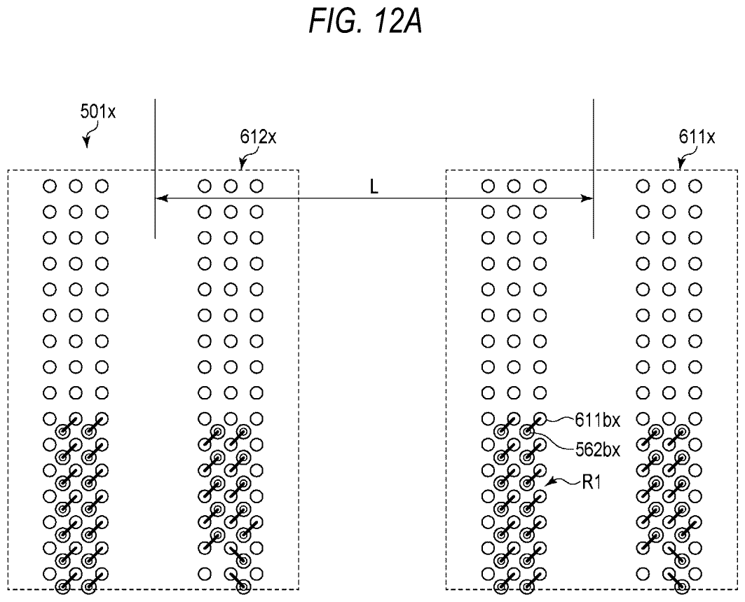

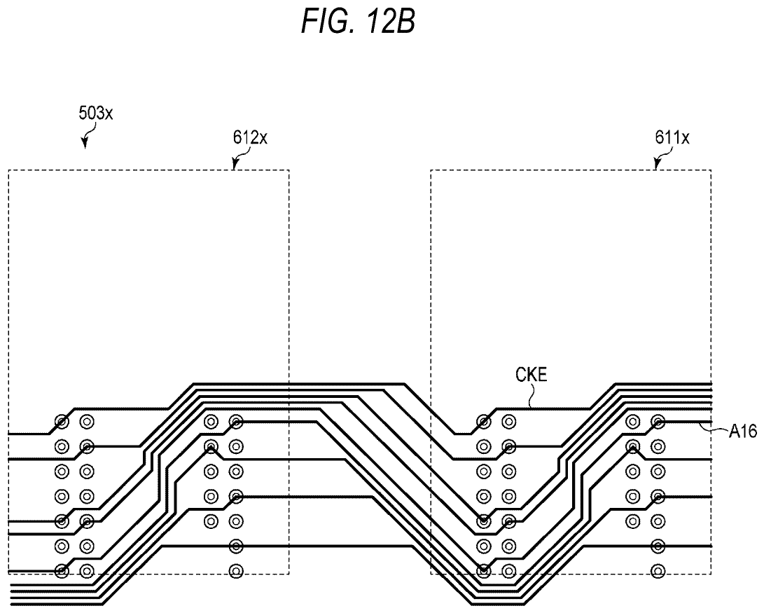

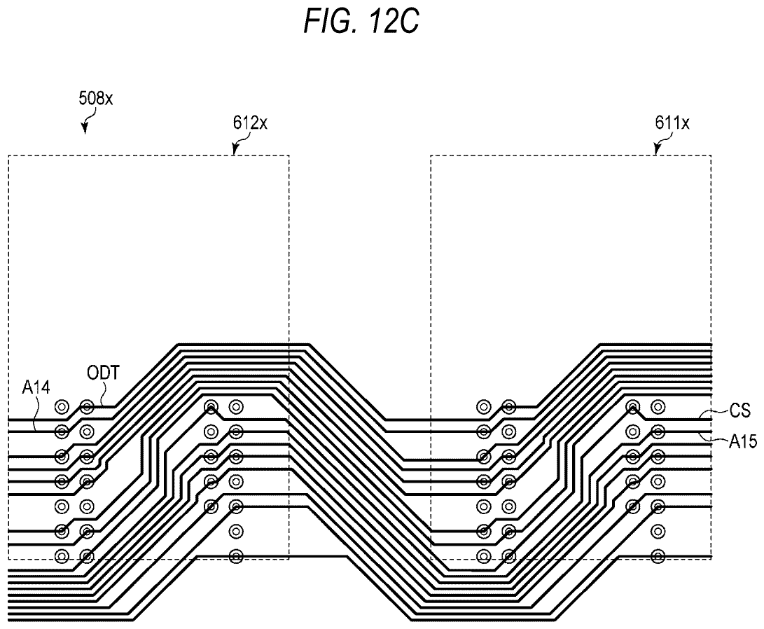

FIGS. 12A to 12C are wiring diagrams schematically illustrating a connection structure between command/address signal lines and vias in a wiring layer of a printed wiring board according to the Reference Example. Here, a part of regions 611x and 612x in which two memory elements are mounted is schematically illustrated. In order to shorten the stub wiring, the vias are arranged so that the wiring between the control terminal and the vias is shortened. For example, the via 562bx is disposed close to the control terminal (ODT signal terminal) 611bx and is connected by wiring. In such an arrangement, since the vias are arranged at the same interval as the interval of the control terminals in the Y direction, the vias are continuously arranged between the control terminals. In the region R1, seven vias are continuously arranged in the Y direction. When one wiring is disposed between the vias, the number of wirings that can cross the region R1 is eight or nine, which is insufficient for twenty-six command/address wirings. For this reason, it is necessary to increase the number of wiring layers and to detour the wiring outside the regions 611x and 612x, where the memories are arranged in the Y direction. Since the wiring becomes longer by the detour, the length of the wiring that does not detour must be adjusted by the meander wiring or the like so as to be substantially the same as the length of the wiring that becomes longer by the detour.

According to the Reference Example, the center interval L between the region 611x and the region 612x, where the memory elements are arranged, is 13.6 mm, which is the same interval as in Example 1. Regarding the CKE signal wiring, the CS signal wiring, the ODT signal wiring, and the A14, A15, and A16 signal wirings, the lengths of the inner layer wirings in the region 611x and the region 612x are as illustrated in Table 2. The length, excluding the memory center interval of 13.6 mm, is 1.3 mm to 5.3 mm. The length of the wiring is increased by the amount by which the wiring is bypassed. The variation in the length was 4.0 mm, and it was confirmed that the variation in the length of the wiring was larger than that in

### Example 1

TABLE 2

| Signal | |
|---|---|
| Name | Length (mm) |
| OKE | 14.8 |
| CS | 18.9 |
| ODT | 15.6 |
| A14 | 15.8 |
| A15 | 18.1 |
| A16 | 18.8 |

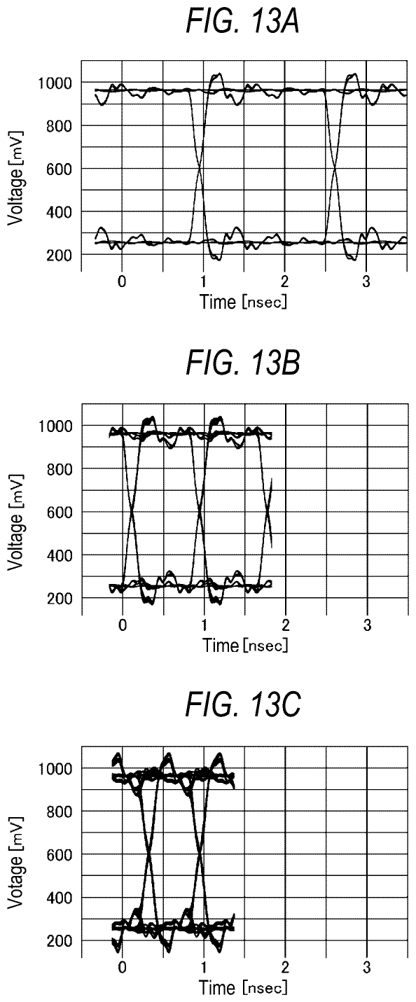

The longer the command/address wiring is, the higher the signal driving capability of the memory controller must be. FIGS. 13A to 13C are waveform simulation result of the command/address signal according to the Reference Example. FIGS. 13A to 13C are waveform simulation results obtained by changing the data transfer rate to 2400 Mbps, 4800 Mbps, and 6400 Mbps, respectively, and the deterioration of the waveforms was compared. Here, the delay time variation (jitter) was observed under a voltage condition in which the rising edge and the falling edge of the waveform crossed each other. In FIGS. 13A to 13C, an increase in the delay time variation was observed, unlike the above-described Example.

As described above, according to Examples 1 and 2 of the present disclosure, unlike the case of the Reference Example, the variation in the length of the wiring is suppressed, and the wiring can be shortened so that the communication speed in the memory interface can be increased.

### Variant Embodiments

The present disclosure is not limited to the embodiments described above, and many modifications are possible within the technical idea of the present disclosure. For example, an example in which a part of the configuration of any of the embodiments is added to another embodiment or an example in which a part of the configuration of another embodiment is replaced with another embodiment is also an embodiment of the present disclosure. In addition, the effects described in the embodiments merely enumerate the most preferable effects generated from the present disclosure, and the effects according to the present disclosure are not limited to those described in the embodiments.

For example, in the above-described embodiment, the memory elements 611 and 612 are arranged on one main surface of the printed wiring board 500 at the same position in the Y direction along the X direction. For this reason, the plurality of wirings extends in parallel in the X direction from the terminal group of the memory element 611 toward the terminal group of the memory element 612. However, the relative positions of the memory element 611 and the memory element 612 are not limited thereto. That is, the memory elements 611 and 612 may be offset in the Y direction. In this case, although the wiring extends in parallel in an oblique direction from the terminal group of the memory element 611 toward the terminal group of the memory element 612, the variation in the length of the wiring between the plurality of wirings can be suppressed as in the case of the above-described embodiment.

In the above-described embodiment, the memory element 611 and the memory element 612 have a common structure, and a positional relationship between the terminal group and the via group in the memory element 611 is common to the positional relationship between the terminal group and the via group in the memory element 612. Therefore, the region R2 (second terminal group) is located between the region R1 (first terminal group) and the region R3 (third terminal group), and the region R3 (third terminal group) is located between the region R2 (second terminal group) and the region R4 (fourth terminal group). However, the structures of the memory elements 611 and 612 may be different from each other. For example, the memory elements 611 and 612 may be mirror-symmetrical to each other. For example, the region R2 (second terminal group) may be located between the region R1 (first terminal group) and the region R3 (third terminal group), and the region R4 (fourth terminal group) may be located between the region R2 (second terminal group) and the region R3 (third terminal group).

Further, in the above-described embodiment, the case where the electronic apparatus includes the imaging apparatus has been described, but the electronic apparatus to which the electronic module of the present disclosure can be applied is not limited to the case where the electronic apparatus includes the imaging apparatus. The electronic apparatus may be, for example, an imaging apparatus, a display device, an information device not including a printing device, or a communication device.

The disclosure of the present specification includes not only the matter explicitly described in the present specification but also all matters that can be grasped from the present specification and the drawings attached to the present specification. Also, the disclosure herein includes a complement of the individual concepts described herein. In other words, for example, when there is a description of “A is B” in this specification, it can be said that this specification discloses that “A is not B” even if a description of “A is not B” is omitted. This is because it is assumed that the case where “A is not B” is considered when “A is B” is described.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-085774, filed May 27, 2024, which is hereby incorporated by reference herein in its entirety.

What is claimed is:

1. An electronic module comprising:
a wiring board; and
a first semiconductor element and a second semiconductor element that are mounted on one main surface of the wiring board,
wherein the first semiconductor element includes a first terminal group and a second terminal group,
wherein the second semiconductor element includes a third terminal group and a fourth terminal group,
wherein the wiring board includes:
a plurality of wiring layers;
a first via group that has a plurality of through-vias respectively connected to a plurality of terminals of the first terminal group;
a second via group that has a plurality of through-vias respectively connected to a plurality of terminals of the second terminal group;
a third via group that has a plurality of through-vias respectively connected to a plurality of terminals of the third terminal group; and
a fourth via group that has a plurality of through-vias respectively connected to a plurality of terminals of the fourth terminal group,
wherein the first terminal group of the first semiconductor element is connected to the third terminal group of the second semiconductor element through the first via group and the third via group, and the second terminal group of the first semiconductor element is connected to the fourth terminal group of the second semiconductor element through the second via group and the fourth via group,
wherein the first via group includes:
a first via that is connected to a first terminal of the first terminal group; and
a second via that is connected to a second terminal of the first terminal group,
wherein the second via group includes:
a third via that is connected to a third terminal of the second terminal group; and
a fourth via that is connected to a fourth terminal of the second terminal group and is adjacent to the third via,
wherein the third via group includes:
a fifth via that is connected to a fifth terminal of the third terminal group; and
a sixth via that is connected to a sixth terminal of the third terminal group,
wherein the first via and the second via are arranged in a first direction, the first via and the second via overlap the first semiconductor element, the third via and the fourth via are arranged in a second direction intersecting the first direction, a virtual straight line that connects the first via and the second via passes between the third via and the fourth via, and a first wiring connecting the first via and the fifth via and a second wiring connecting the second via and the sixth via pass between the third via and the fourth via.

2. The electronic module according to claim 1,
wherein the fourth via group includes:
a seventh via that is connected to a seventh terminal of the fourth terminal group; and
an eighth via that is connected to an eighth terminal of the fourth terminal group and is adjacent to the seventh via,
wherein the seventh via and the eighth via are arranged in the second direction,
wherein the first wiring and the second wiring pass between a third wiring connecting the third via and the seventh via and a fourth wiring connecting the fourth via and the eighth via.

3. The electronic module according to claim 2, wherein the fifth via and the sixth via are disposed between the third wiring and the fourth wiring.

4. The electronic module according to claim 2, wherein the fifth via and the sixth via are arranged in the first direction, and a virtual straight line connecting the fifth via and the sixth via passes between the seventh via and the eighth via.

5. The electronic module according to claim 1, wherein a virtual straight line connecting the first via and the second via and a virtual straight line connecting the fifth via and the sixth via are positioned on the same virtual straight line.

6. The electronic module according to claim 1,
wherein the first via group includes a ninth via connected to a ninth terminal of the first terminal group,
wherein the virtual straight line connecting the first via and the second via passes through the ninth via, and
wherein the second terminal and the ninth terminal are arranged in a third direction intersecting the first direction.

7. The electronic module according to claim 6, wherein the ninth via is disposed between the first via and the second via.

8. The electronic module according to claim 6, wherein the first terminal and the second terminal are arranged in a fourth direction intersecting the third direction.

9. The electronic module according to claim 6,
wherein the fourth via group includes:
a seventh via that is connected to a seventh terminal of the fourth terminal group; and
an eighth via that is connected to an eighth terminal of the fourth terminal group and is adjacent to the seventh via, and
wherein the third via group includes a tenth via connected to a tenth terminal of the third terminal group,
a fifth wiring connecting the ninth via and the tenth via passes between the seventh via and the eighth via.

10. The electronic module according to claim 8,
wherein the third via group includes a tenth via connected to a tenth terminal of the third terminal group, and
wherein the tenth via is disposed between the fifth via and the sixth via.

11. The electronic module according to claim 9,
wherein the first wiring and the second wiring are provided in a first wiring layer of the plurality of wiring layers, and
wherein the fifth wiring is provided in a second wiring layer of the plurality of wiring layers.

12. The electronic module according to claim 1, wherein the difference between the length of the first wiring and the length of the second wiring is less than or equal to 10% of the length of either the first wiring or the second wiring.

13. The electronic module according to claim 1, wherein the first wiring and the second wiring have a fly-by wiring structure.

14. The electronic module according to claim 1,
wherein, through the first wiring, a first signal is supplied to the first semiconductor element and the second semiconductor element, and
wherein, through the second wiring, a second signal is supplied to the first semiconductor element and the second semiconductor element.

15. The electronic module according to claim 1,
wherein the first semiconductor element and the second semiconductor element are memories, and
wherein the electronic module further comprises a memory controller that is mounted on the wiring board and is configured to input and output data to and from the first semiconductor element and the second semiconductor element.

16. The electronic module according to claim 1, wherein the first terminal, the second terminal, the fifth terminal, and the sixth terminal are control terminals.

17. The electronic module according to claim 1, wherein the first terminal group, the second terminal group, the third terminal group, and the fourth terminal group have a ball grid array structure.

18. The electronic module according to claim 1, further comprising
a plurality of connectors that are mounted on the wiring board.

19. An electronic apparatus comprising:
a first electronic module, which is the electronic module according to claim 1; and
a second electronic module; and
a wiring member that connects the first electronic module and the second electronic module to each other.

20. An electronic apparatus comprising:
an image acquisition device; and
a circuit device that outputs image data based on an image signal acquired by the image acquisition device,
wherein the circuit device includes the electronic module according to claim 1.

21. The electronic apparatus according to claim 20 comprises an image forming apparatus that forms an image based on the image data.

22. An electronic apparatus comprising:
a circuit device that outputs image data; and
an image forming apparatus that forms an image based on the image data,
wherein the circuit device includes the electronic module according to claim 1.

23. The electronic apparatus according to claim 22, wherein the image forming apparatus is a display device.

24. The electronic apparatus according to claim 22, wherein the image forming apparatus is a printing apparatus.
